(19) United States
(12) Patent Application Publication
(10) Pub. No.: US 2016/0336512 A1
(43) Pub. Date: Nov. 17, 2016

(54) METHOD OF FORMING ORGANIC SEMICONDUCTOR FILM AND ORGANIC SEMICONDUCTOR FILM FORMING DEVICE

(71) Applicant: FUJIFILM CORPORATION, Tokyo (JP)

(72) Inventors: Kouki TAKAHASHI, Kanagawa (JP); Yoshihisa USAMI, Kanagawa (JP)

(73) Assignee: FUJIFILM CORPORATION, Tokyo (JP)

(21) Appl. No.: 15/218,104

(22) Filed: Jul. 25, 2016

Related U.S. Application Data
(63) Continuation of application No. PCT/JP2015/055028, filed on Feb. 23, 2015.

(30) Foreign Application Priority Data
Mar. 3, 2014 (JP) 2014-040349

(51) Int. Cl. H01L 51/00; B05C 11/08

(52) U.S. Cl. CPC H01L 51/0003; H01L 51/0028; B05C 11/08

(57) ABSTRACT

Provided is a method of forming an organic semiconductor film which uses a shielding member for covering a solution, including: obtaining a state in which a solution that is in contact with the shielding member and contains an organic semiconductor material and a solvent is present, between the substrate and the shielding member positioned parallel to and separated from the substrate, in a predetermined position on the substrate placed on a stage; and moving the stage and the shielding member relative to each other in a predetermined direction. In this manner, an organic semiconductor film having a large area and excellent crystallinity is formed in a desired position on the substrate.

### CROSS-REFERENCE TO RELATED APPLICATIONS

This application is a Continuation of PCT International Application No. PCT/JP2015/055028 filed on Feb. 23, 2015, which claims priority under 35 U.S.C. §119(a) to Japanese Patent Application No. 2014-040349 filed on Mar. 3, 2014. The above application is hereby expressly incorporated by reference, in its entirety, into the present application.

### BACKGROUND OF THE INVENTION

1. Field of the Invention

The present invention relates to a method of forming an organic semiconductor film and an organic semiconductor film forming device which are used to manufacture a thin film transistor using an organic semiconductor material.

2. Description of the Related Art

From the viewpoints of weight reduction, low cost, and softening, an organic semiconductor element having an organic semiconductor film (organic semiconductor layer) formed of an organic semiconductor material has been used for thin film transistors (TFTs) used for a liquid crystal display or an organic EL display and devices used for logic circuits such as an RFID (RF tag) or a memory.

In manufacture of an organic semiconductor element, a wet process such as a coating method is known as an example of a method of forming an organic semiconductor film.

As an example, according to the wet process, an organic semiconductor film is formed by spin-coating a substrate with a solution obtained by dissolving an organic semiconductor material in a solvent and evaporating the solvent from the solution so that the organic semiconductor material is deposited on the substrate.

Further, in order to obtain an organic semiconductor film with high mobility, it is important to improve the crystallinity of the organic semiconductor film. For this reason, in regard to formation of an organic semiconductor film according to a wet process, various methods for improving the crystallinity of an organic semiconductor film have been suggested.

In addition, in recent years, for the purpose of improving productivity, it has been desired that an organic semiconductor film with excellent crystallinity has been formed to have a large area and to be uniform.

Regarding such problems, a method (thin film forming method) described in JP2006-66662A is known as a method of forming an organic semiconductor film with excellent crystallinity to have a large area.

In the method described in JP2006-66662A, a solution formed by dissolving an organic semiconductor material in a solvent is put into a container and then heated. A substrate and an auxiliary plate which are arranged in parallel to each other due to being separated by a predetermined interval are immersed in the solution and then the substrate is pulled up from the solution in a state in which the substrate and the auxiliary plate are maintained parallel to each other. At this time, the solution is sucked up by the surface tension between the substrate and the auxiliary plate, and the solution between the substrate and the auxiliary plate is always continuous with the solution in the container via a liquid layer. The temperature of the solution adhered to the substrate gradually decreases due to the pulling up, and the organic semiconductor material is deposited on the surface of the substrate, thereby forming an organic semiconductor film.

### SUMMARY OF THE INVENTION

According to this production method, since an organic semiconductor film can be formed on the entire surface of the substrate, it is possible to form an organic semiconductor film having a large area in accordance with the size of the substrate.

In addition, since deposition of the organic semiconductor material is started from the position on the substrate, which has been previously pulled up, and progresses in the pulling up direction, an organic semiconductor film with excellent crystallinity can be obtained.

Meanwhile, according to the method described in JP2006-66662A, an organic semiconductor film is formed on the entire surface of the substrate. Therefore, an organic semiconductor film cannot be formed only in a desired position on the substrate. Further, the shape of the organic semiconductor film (plane shape) is determined by the shape of the substrate.

That is, according to this method, an organic semiconductor film with excellent crystallinity can be formed to have a large area, but an organic semiconductor film having a desired shape cannot be formed in a desired position on the substrate. For this reason, an unnecessary organic semiconductor film on the substrate needs to be removed in a subsequent process and this results in waste of the organic semiconductor material.

Moreover, recently, in order to obtain an organic semiconductor film with higher mobility, there has been a demand for forming an organic semiconductor film on a substrate with liquid repellency with respect to a solution used to form an organic semiconductor film.

However, according to the method described in JP2006-66662A, it is necessary for the substrate to be inclined and pulled up from the container filled with a solution. Therefore, it is difficult to form an organic semiconductor film on a substrate having water repellency using the method described in JP2006-66662A.

An object of the present invention is to solve the above-described problems in the related art, and to provide a method of forming an organic semiconductor film which has a large area, is positioned in a predetermined position on a substrate, and has a desired shape and excellent crystallinity; and an organic semiconductor film forming, device which performs the method of forming an organic semiconductor film.

In order to achieve the above-described object, the present invention provides a method of forming an organic semiconductor film which uses a shielding member for covering, a solution containing an organic semiconductor material and a solvent when forming the organic semiconductor film on at least a part of a substrate using the solution, the method comprising: a process of placing the substrate on a stage; a process of coating a predetermined position on the surface of the substrate with the solution and positioning the shielding member parallel to the substrate by bringing the shielding member into contact with the solution and separating the shielding member from the substrate or a process of positioning the shielding member in a predetermined position on the substrate parallel to the substrate and separated from the substrate and filling the space between the shielding member and the substrate with the solution by bringing the solution into contact with the shielding member; and a process of moving the shielding member and the stage relatively parallel to each other in a predetermined direction, from the state in which the solution is present between the shielding member and the substrate.

In the method of forming an organic semiconductor film of the present invention, it is preferable that the surface of the shielding member in contact with the solution is water-repellent with respect to the solution.

Further, it is preferable that the surface energy of the shielding member is lower than the surface energy of the substrate.

Further, it is preferable that the temperature of at least one of the shielding member or the stage is controlled.

Further, it is preferable that the organic semiconductor material in the solution exposed from the shielding, member due to the relative movement between the shielding member and the stage is forcibly deposited.

Further, it is preferable that the forced deposition of the organic semiconductor material is carried out by blowing air into the solution.

Furthermore, it is preferable that the surface of the substrate is made to be horizontal and placed on the stage.

Further, the present invention provides an organic semiconductor film forming device comprising: a stage on which a substrate is placed; a shielding member which covers a solution containing an organic semiconductor material and a solvent; solution supply means for supplying the solution to a predetermined position on the substrate placed on the stage; position control means for positioning the shielding member in a predetermined position with respect to the surface of the stage on which the substrate is placed, in a state in which the shielding member is separated from the stage and parallel to the surface of the stage on which the substrate is placed; and relative moving means for moving the shielding member and the stage relatively parallel to each other in a predetermined direction.

It is preferable that the organic semiconductor film forming device of the present invention further comprises at least one of temperature adjusting means for the stage or temperature adjusting means for the shielding member.

Further, it is preferable that the organic semiconductor film forming, device further comprises deposition means for allowing the organic semiconductor material to be forcibly deposited from the solution.

Further, it is preferable that the deposition means is air blowing, means. Furthermore, it is preferable that the organic semiconductor film forming device further comprises angle adjusting means for the surface of the stage.

According to the present invention, it is possible to form an organic semiconductor film which has a large area, is positioned in a predetermined position on a substrate, and has a desired shape and excellent crystallinity.

### BRIEF DESCRIPTION OF THE DRAWINGS

FIG. 1A is a front view schematically illustrating an example of an organic semiconductor film forming device of the present invention that performs a method of forming an organic semiconductor film of the present invention. FIG. 1B is a plan view schematically illustrating an example of the organic semiconductor film forming device of the present invention that performs the method of forming an organic semiconductor film of the present invention.

FIGS. 2A to 2D are schematic views for describing actions of the organic semiconductor film forming device illustrated in FIGS. 1A and 1B.

FIG. 3 is a plan view schematically illustrating another example of the organic semiconductor film forming device of the present invention that performs the method of forming an organic semiconductor film of the present invention.

FIGS. 4A and 4B are plan views schematically illustrating another example of a shielding plate used for the organic semiconductor film forming device of the present invention that performs the method of forming an organic semiconductor film of the present invention.

FIGS. 5A and 5B are images obtained by imaging an organic semiconductor film prepared in the examples of the present invention and treating the images for an output.

FIGS. 6A and 6B are images obtained by imaging an organic semiconductor film prepared in the comparative examples of the present invention and treating the images for an output.

### DESCRIPTION OF THE PREFERRED EMBODIMENTS

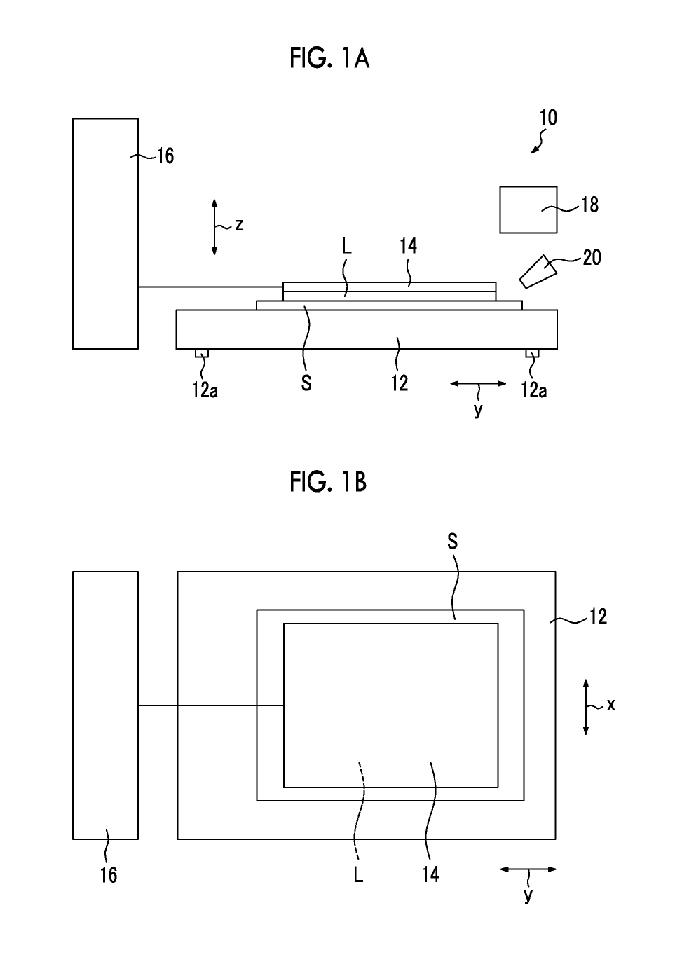

FIGS. 1A and 1B schematically illustrate examples of an organic semiconductor film forming device of the present invention that performs a method of forming an organic semiconductor film of the present invention. FIG. 1A is a front view (when seen from the surface direction of the substrate that performs film formation) and FIG. 1B is a plan view (when seen from the direction perpendicular to the surface direction of the substrate that performs film formation (top view)).

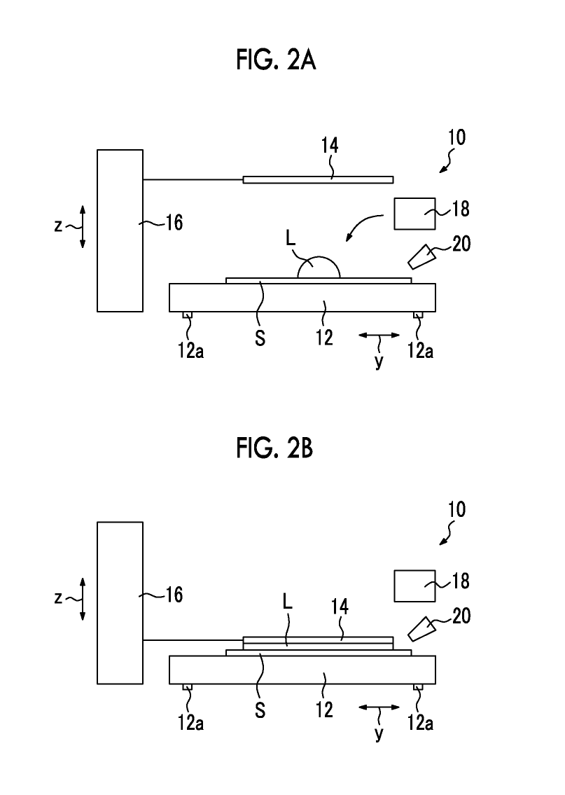

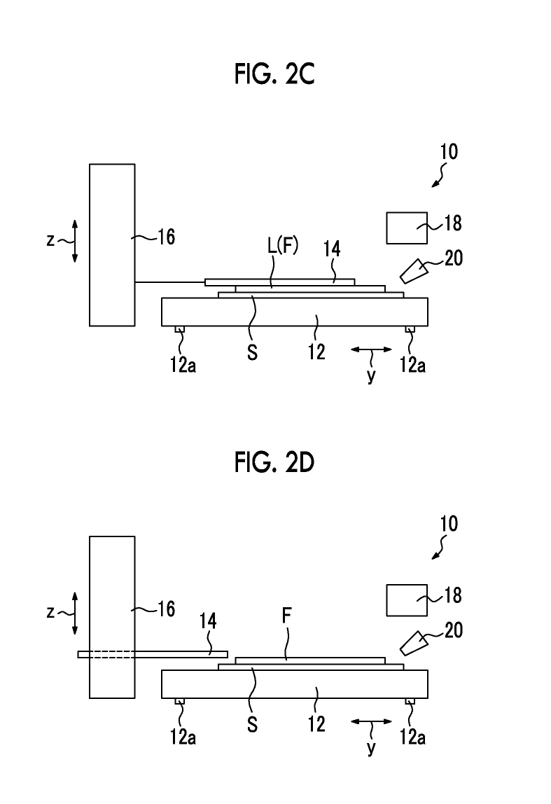

A forming device 10 illustrated in FIGS. 1A and 1B is a device for forming an organic semiconductor film F on the surface of a substrate S using a solution L containing an organic semiconductor material and a solvent (see FIG. 2D). Further, the organic semiconductor film F is a film having an organic semiconductor material as a main component.

In the examples of the figures, the forming device 10 is basically configured to include a stage 12, a shielding plate 14, moving means 16, coating means 18, and air blowing means 20.

Further, the forming device 10 may further include various sensors and necessary members such as temperature detecting means in addition to the members illustrated in the figures.

In the present invention, plate-like materials (sheet-like materials/films) formed of various materials, for example, metals, ceramics, glass, and plastic, can be used as the substrate S as long as the materials are capable of forming an organic semiconductor film F by being coated with the solution L.

A plastic film can be also suitably used as the substrate S.

Examples of the material of the plastic film which can be used for the substrate S include thermoplastic resins such as a polyester resin, a methacrylic resin, a methacrylic acid-maleic acid copolymer, a polystyrene resin, a fluororesin, polyimide, a fluoride polyimide resin, a polyamide resin, a polyamide imide resin, a polyetherimide resin, a cellulose acylate resin, a polyurethane resin, a polyether ether ketone resin, a polycarbonate resin, an alicyclic polyolefin resin, a polyarylate resin, a polyether sulfone resin, a polysulfone resin, a cycloolefin copolymer, a fluorene ring-modified carbonate resin, an alicyclic-modified polycarbonate resin, a fluorene ring-modified polyester resin, and an acryloyl compound.

Particularly, it is preferable that the plastic film is formed of a material ha wing heat resistance.

Specifically, it is preferable that the plastic film has heat resistance satisfying at least one physical property of a glass transition temperature (Tg) of 100° C. or higher or a linear thermal expansion coefficient of 40 ppm/° C. or less. Further, it is also preferable that the plastic film is formed of a material having high transparency with respect to light. The Tg or the linear thermal expansion coefficient of the plastic film can be adjusted using, an additive or the like.

Examples of such thermoplastic resins having excellent heat resistance include polyethylene naphthalate (PEN: 120° C.), polycarbonate (PC:140° C.), alicyclic polyolefin (for example, ZEONOR 1600: 160° C., manufactured by ZEON CORPORATION), polyacrylate (PAr: 210° C.), polyether sulfone (PES: 220° C.), polysulfone (PSF: 190° C.), a cycloolefin copolymer (COC: compound described in JP2001-150584A: 162° C.), a fluorene ring-modified polycarbonate (BCF-PC: compound described in JP2000-227603A: 225° C.), alicyclic-modified polycarbonate (IP-PC: compound described in JP2000-227603A: 205° C.), an acryloyl compound (compound described in JP2002-80616A: 300° C. or higher), and polyimide. Further, Tg values of respective materials are shown in parentheses in the above-described thermoplastic resins. A plastic film formed of these thermoplastic resins having excellent heat resistance is suitable as the substrate S in the present invention.

Moreover, materials having various configurations, in the manufacture of an organic semiconductor element, can be used as the substrate S that forms an organic semiconductor film, in addition to a simple plate-like material exemplified in the figures.

As an example, the substrate S may be a material in which an insulating layer is formed on a part or the entire surface of a support, a material in which a gate electrode is formed on a support and an insulating-layer is formed by covering the support and the gate electrode, or a material in which an insulating layer is formed on the surface of a support which becomes a gate electrode and a source electrode and a drain electrode are formed thereon. In this case, the support becomes a substrate of a semiconductor element.

That is, the present invention can be used for formation of an organic semiconductor film (organic semiconductor layer) in a process of manufacturing various known organic semiconductor elements such as a bottom-gate bottom-contact type organic semiconductor element, a top-gate bottom-contact type organic semiconductor element, a bottom-gate top-contact type organic semiconductor element, and a top-gate top-contact type organic semiconductor element.

Moreover, as such a support (substrate of a semiconductor element), those exemplified in the section of the substrate S described above can be used here.

Further, the substrate S may be liquid-repellent with respect to the solution L which becomes the organic semiconductor film F.

In formation of the organic semiconductor film F using a coating method, it is known that the arrangement of molecules of the organic semiconductor material is made to be proper so that high mobility can be obtained by means of using the substrate S having water repellency with respect to the solution L which becomes the organic semiconductor film F, and this also depends on the composition or the like of the solution L. Accordingly, depending on the type of the organic semiconductor material or the solvent contained in the solution L, in many cases, it is preferable to use the substrate S with liquid repellency with respect to the solution L.

Here, according to the method described in JP2006-66662A, since it is necessary to pull up the substrate and the auxiliary plate from the container filled with the solution in an inclined state, a substrate (and/or auxiliary plate) with liquid repellency with respect to the solution cannot be used.

Meanwhile, in the present invention, preferably, the surface of the substrate S (upper surface of the stage 12) placed on the upper surface of the stage 12 is made to be horizontal, and the surface of the substrate S is coated with the solution L to form the organic semiconductor film F. Accordingly, even in a case of the substrate S with liquid repellency with respect to the solution L, the solution L is desirably maintained on the substrate S so that the organic semiconductor film S can be formed.

The stage 12 is used for placing the substrate S thereon. As the stage 12, stages with various shapes formed of various materials can be used as long as those have a plane so that the substrate S can be stably placed thereon.

The stage 12 in the examples of the figures is a housing having a rectangular parallelepiped shape.

The stage 12 has leg portions 12a, whose height (length) is adjustable, on the four corners of the lower surface thereof. Therefore, the angle of the upper surface of the stage 12 is adjusted by adjusting the height of the leg portions 12a and then the surface of the substrate S placed on the upper surface of the stage 12 can be made to be horizontal.

In addition, the height of the leg portions 12a can be adjusted using known methods such as a method of using a screw.

According to a preferred aspect, temperature adjusting means for adjusting the temperature of the upper surface is incorporated in the stage 12. The temperature adjusting means may heat the upper surface of the stage 12, cool the upper surface thereof, or may be capable of heating and cooling the upper surface thereof.

When the temperature adjusting means is incorporated in the stage 12, drying of the solution L described below, that is, formation of the organic semiconductor film F resulting from the deposition of the organic semiconductor material can be appropriately controlled.

In addition, in the present invention, the temperature adjusting means of the stage 12 may adjusts the temperature of the upper surface from the outside of the stage 12 without being incorporated in the stage 12. Further, the temperature adjusting means incorporated in the stage 12 and the temperature adjusting means provided on the outside the stage 12 may be used in combination.

As the temperature adjusting means on the upper surface of the stage 12, known temperature control means such as various heaters, circulation of a temperature adjusting medium, and a Peltier device can be used.

The shielding plate 14 is a member that covers the solution L and interposes the solution L with the substrate S therebetween. The shielding plate 14 is a shielding member of the present invention.

In the examples of the figures, the lower surface of the shielding plate 14 is made to be parallel to the upper surface of the stage 12 and is held by the moving means 16 described below. Further, the shielding plate 14 three-dimensionally moves, by the moving means 16, in an x-direction (transverse direction) in the plane direction of the upper surface of the stage 12, a y-direction perpendicular to the x-direction in the same plane direction, and a z-direction (height direction) perpendicular to an x-y direction.

As will be described later, according to the present invention, when the shielding plate 14 and the moving means 16 are included, it is possible to form an organic semiconductor film F with excellent crystallinity, which is positioned in a desired position on the substrate S and has a desired shape and a desired size, corresponding to the substrate S having a large area. Moreover, in the forming device 10 in the examples of the figures, the moving means 16 serves as position control means and relative moving means in the present invention.

In the examples of the figures, the shielding plate 14 is a plate-like member. However, members with various shapes such as a box or a hemisphere having a plane can be used as the shielding plate 14 as long as the members have a plane which can be made to be parallel to the upper surface of the stage 12.

Further, various materials such as metals, glass, ceramics, and plastic can be used as the materials for forming the shielding plate 14 as long as a plane which can be made to be parallel to the upper surface of the stage 12 can be formed from the materials.

It is preferable that at least the surface of the shielding plate 14, which faces the stage 12, is liquid-repellent with respect to the solution L. The surface of the shielding plate 14 facing the stage 12 is the surface that covers the solution L and is also the surface facing the substrate S.

As will be described later, in the present invention, the organic semiconductor film F is formed by moving the shielding plate 14 to the moving means 16 side in the y-direction in a state of being parallel with the upper surface of the stage 12 (substrate S) after the solution L is interposed between the shielding plate 14 and the substrate S.

Accordingly, when the surface of the shielding plate 14 facing the stage 12 is made to be liquid-repellent with respect to the solution L, it is possible to prevent deposition of the organic semiconductor material caused by the shielding plate 14 pulling the solution L during the parallel movement and then the solution L being adhered to the shielding plate 14. Moreover, the shape of the solution L during the movement of the shielding plate 14 can be also stabilized.

In addition, it is preferable that the surface energy of at least the surface of the shielding plate 14 facing the stage 12 is lower than that of the substrate S. particularly, as described above, in a case where the substrate S is liquid-repellent with respect to the solution L, it is preferable that the surface energy of at least the surface of the shielding plate 14 facing the stage 12 is lower than that of the substrate S.

In this manner, for example, even in a case where the substrate S is liquid-repellent with respect to the solution L, the shielding plate 14 can be stably moved in a state of being parallel to the upper surface of the stage 12 without the shielding plate 14 pulling the solution L.

The liquid repellency of the shielding plate 14 with respect to the solution L in the surface facing the stage 12 can be achieved by a known method. Examples of the method include a method of forming the shielding plate 14 with materials having liquid repellency with respect to the solution L and a method of carrying out a liquid-repellent treatment such as a fluorine treatment of coating the surface of the shielding plate 14 facing the stage 12 with polytetrafluoroethylene.

According to a preferred aspect, temperature adjusting means for adjusting the temperature of the surface of the shielding plate facing the stage 12 is incorporated in the shielding plate 14. When the temperature adjusting means is incorporated in the shielding plate 14, it is possible to appropriately control the formation of the organic semiconductor film F resulting from the deposition of the organic semiconductor material similar to the stage 12 described above.

Moreover, similar to the stage 12, the temperature adjusting means of the shielding plate 14 may adjust the temperature of the shielding plate 14 from the outside, and the temperature adjusting means incorporated in the shielding plate 14 and the temperature adjusting means provided on the outside the shielding plate 14 may be used in combination.

In addition, similar to the temperature adjusting means on the upper surface of the stage 12, various known temperature control means can be used as the temperature adjusting means of the shielding plate 14.

In the present invention, the stage 12 and the shielding plate 14 may not include the temperature adjusting means, but it is preferable that any one of the stage 12 and the shielding plate 14 includes the temperature adjusting means and more preferable that both of the stage 12 and the shielding plate 14 include the temperature adjusting means.

The forming device 10 may include only one kind of shielding plate 14 (shielding member). Alternatively, plural kinds of shielding plates 14 with different shapes are prepared and can be suitably replaced therefor according to the organic semiconductor element or the like to be formed.

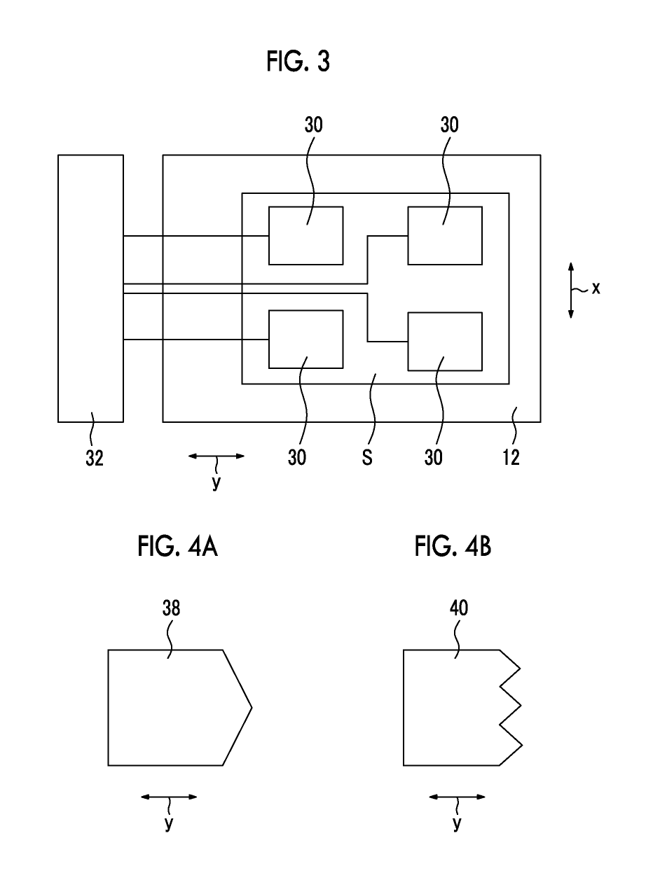

The same applies to a case where an organic semiconductor film F is formed using a plurality of the shielding plates 30 at the same time, illustrated in FIG. 3. Further, at the time of formation of organic semiconductor film carried out once, a plurality of organic semiconductor films with different shapes may be formed using different kinds of shielding plates.

The moving means 16 holds the shielding plate 14 by making the lower surface of the shielding plate 14 in parallel with the upper surface of the stage 12 and moves the held shielding plate 14 in the three-dimensional direction of x-y-z. In other words, the shielding plate 14 is mounted on the moving means 16 in a state in which the lower surface of the shielding plate 14 is made to be parallel with the upper surface of the stage 12 and the moving means 16 moves the held shielding plate 14 in the three-dimensional direction of x-y-z.

Specifically, when the shielding plate 14 is lifted by the moving means 16, the substrate S can be coated with the solution L using the coating means 18 described below. When the shielding plate 14 is dropped by the moving means 16, the solution L is interposed between the shielding plate 14 and the substrate S. Further, when the shielding plate 14 is moved by the moving means 16 in the x-direction and/or the y-direction, the shielding plate 14 moves to a desired position in the plane direction of the substrate S (stage 12). The desired position to which the shielding plate 14 moves in the plane direction of the substrate S is a position in which the organic semiconductor film F is formed in the substrate S. As will be described later, when the shielding plate 14 moves in the x-y direction, the organic semiconductor film F can be formed in a desired position on the substrate S.

In addition, when the moving means 16 moves the shielding plate 14 to the moving means 16 side (left side of the figure) in the y-direction in a state in which the shielding plate 14 is parallel to the upper surface of the stage 12, the shielding plate 14 and the stage 12 (substrate S) are moved relative to each other in the y-direction.

In others words, in the forming device 10 in the examples of the figures, the moving means 16 serves as position control means for positioning the shielding plate 14 in a predetermined position with respect to the upper surface of the stage 12 in a state in which the shielding plate 14 is separated from the stage 12 and is parallel to the upper surface of the stage 12 and relative moving means for moving the shielding plate 14 and the stage 12 relatively parallel to each other in a predetermined direction.

As the moving means 16, a combination of a moving device that moves a plate-like material in the two-dimensional direction and a lifting device that lifts and lowers the moving device; a combination of a lifting device that lifts and lowers a plate-like material and a moving device that moves the lifting device in the two-dimensional direction; and various known moving means for moving plate-like materials in the three-dimensional direction, such as a moving device for a plate-like material using an industrial robot can be used.

Moreover, in the examples of the figures, the forming device has a configuration of the position control means and the relative moving means of the present invention by means of including the moving means 16 for moving the shielding plate 14 in the three-dimensional direction. However, various configurations can be used in the present invention other than those.

For example, the moving means 16 may be used as the position control means only for moving the shielding plate 14 three-dimensionally and the relative moving means for moving the shielding plate 14 and the stage 12 relatively parallel to each other by moving the stage 12 in the y-direction. Alternatively, the position control means and the relative moving means of the present invention may be configured by means of including the moving means for moving the shielding plate 14 in the x-y direction and the lifting means for lifting and lowering the stage 12 in the z direction. Alternatively, the position control means and the relative moving means of the present invention may be configured by means of including the lifting means for lifting and lowering the shielding plate 14 in the z direction and the moving means for moving the stage 12 in the x-y direction. Alternatively, the position control means and the relative moving means of the present invention may be configured by means of including the moving and lifting means for moving the shielding plate 14 in the x direction and lifts and lowers the shielding plate 14 in the z direction and the moving means for moving the stage 12 in the y direction. Alternatively, the position control means and the relative moving means of the present invention may be configured by means of including the moving means for moving the stage 12 in the three-dimensional direction of x-y-z. Alternatively, the position control means and the relative moving means of the present invention may be configured by means of including the lifting means for lifting and lowering the shielding plate 14 and the moving means for moving the stage 12 in the y direction.

In the present invention, the moving means 16 may hold a plurality of the shielding plates 14 and moves the shielding plates 14 (see FIG. 3).

Moreover, the moving means 16 may be a member which is capable of changing the number of the shielding plates 14 to be held. Further, the moving means 16 may be a member which is capable of changing the number of the shielding plates 14 to be moved.

The coating means 18 coats a desired position on the surface of the substrate S with the solution L. As described above, the desired position on the surface of the substrate S is a position in which a target organic semiconductor film F is formed.

The solution L is a solution (coating material/coating solution) including an organic semiconductor material and a solvent.

In the present invention, various known materials used for an organic semiconductor film to be formed according to a coating method such as a so-called wet process can be used as the organic semiconductor material in the manufacture of an organic semiconductor element.

Specific examples thereof include a pentacene derivative such as 6,13-bis(triisopropylsilylethynyl) pentacene (TIPS pentacene), an anthradithiophene derivative such as 5,11-bis(triethylsilylethynyl) anthradithiophene (TES-ADT), a benzodithiophene (BDT) derivative, a benzothienobenzothiophene (BTBT) derivative, a dinaphthothienothiophene (DNTT) derivative, a 6,12-dioxaanthanthrene(perixanthenoxanthene) derivative, a naphthalene tetracarboxylic acid diimide (NTCDI) derivative, a perylene tetracarboxylic acid diimide (PTCDI) derivative, a polythiophene derivative, a poly(2,5-bis(thiophene-2-yl)thieno[3,2-b]thiophene) (PBTTT) derivative, a tetracyanoquinodimethane (TCNQ) derivative, oligothiophenes, phthalocyanines, and fullerenes.

Various solvents can be used as the solvent contained in the solution L as long as the solvents can dissolve organic semiconductor materials to be used.

For example, in a case where the organic semiconductor material is TIPS pentacene or TES-ADT, preferred examples thereof include aromatic compounds such as toluene, xylene, mesitylene, 1,2,3,4-tetrahydronaphthalene (tetralin), chlorobenzene, dichlorobenzene, and anisole.

The concentration of the solution L may be appropriately set according to the organic semiconductor material to be used, the solvent, or the thickness of the organic semiconductor film to be formed.

The solution L may contain a thickener, a crystallization agent, or an antioxidant, if necessary, in addition to the organic semiconductor material and the solvent.

Various coating means can be used as the coating means 18 as long as a desired position on the surface of the substrate S (stage 12) can be coated with the solution L having a target amount.

Examples of the coating means include an ink-jet printer, a dispenser, a dispenser robot, and a syringe pump.

In addition, the coating means 18 may include moving means (scanning means) for moving in the x-direction and/or the y-direction as needed. Alternatively, the coating means 18 may be mounted on the moving means for moving in the x-direction and/or the y-direction as needed.

The air blowing means 20 is provided according to a preferred aspect. When the air blowing means 20 blows air to the solution L exposed due to the movement of the shielding plate 14, in the y-direction, interposing the solution L with the substrate S, the drying of the solution L is promoted and the organic semiconductor material in the solution L is deposited.

That is, the air blowing means 20 is deposition means for forcibly depositing the organic semiconductor material from the solution L. When the deposition means is included, the organic semiconductor material is suitably deposited and the organic semiconductor film F can be formed even in the case where the substrate S is liquid-repellent with respect to the solution L.

Various known air blowing means such as a fan and a blower can be used as the air blowing means 20.

Various gases can be used as the gas blown by the air blowing means 20 unless the gases adversely affect the solution L or the organic semiconductor film F.

Examples thereof include air, nitrogen gas, and argon gas.

Further, the air velocity or the air volume of the air blowing means 20, which does not disturb the solution L and is capable of drying the solution L may be appropriately set according to the size of the solution L, the film thickness of the solution L, and the boiling point of the solvent contained in the solution L. The size of the solution L mainly indicates the length of the solution L in the x-direction.

Specifically, the air velocity thereof is preferably in a range of 0.1 m/sec to 15 m/sec, more preferably in a range of 0.1 m/sec to 10 msec, and still more preferably in a range of 0.1 m/sec to 1 m/sec.

In addition to the air blowing means 20, various members can be used as the deposition means for forcibly depositing the organic semiconductor material from the solution L as long as the members cause the organic semiconductor material to be forcibly deposited from the solution L.

Specific examples thereof include heating means for promoting evaporation of the solution L, cooling means for cooling the solution L so that the solubility is decreased and the organic semiconductor material is deposited, and means for dropping a poor solvent so that the solubility is decreased and the organic semiconductor material is deposited.

Hereinafter, a method of forming an organic semiconductor film of the present invention will be described in more detail with reference to FIGS. 2A to 2D.

First, as conceptually illustrated in FIG. 2A, the shielding plate 14 is lifted by the moving means 16 and the substrate S is placed in a predetermined position on the upper surface of the stage 12. At this time, in order to make the surface of the substrate S horizontal, it is preferable that the height of the leg portions 12a of the stage 12 is adjusted. In this manner, even in a case where the substrate S with liquid repellency with respect to the solution L is used, the organic semiconductor film F can be suitably formed on the surface of the substrate S.

Further, the position of the shielding plate 14 in the x-y direction is moved, by the moving means 16, to a desired position on the substrate S, that is, a position in which a target organic semiconductor film F is formed.

Moreover, depending on the configuration of the device, the shielding plate 14 may be moved to a position on the substrate S, in which the organic semiconductor film F is formed, by moving the stage 12 as described above.

Next, a desired position, that is, a position in which a target organic semiconductor film F is formed is coated (dropped) with the solution L using the coating means 18. The center or the vicinity of the center of the position in which the organic semiconductor film F is formed may be coated with the solution L.

Here, the coating amount of the solution L is appropriately set according to the thickness of a target solution L and the area of a target organic semiconductor film F such that the solution L properly fills the entire area between the shielding plate 14 and the substrate S. The film thickness of the solution L typically indicates an interval between the shielding plate 14 and the substrate S set for formation of the organic semiconductor film F. The area of the organic semiconductor film F typically indicates the area of the shielding plate 14.

Next, as conceptually illustrated in FIG. 2B, the shielding plate 14 is dropped until the interval between the substrate S (stage 12) and the shielding plate 14 becomes a predetermined interval, the shielding plate 14 is brought into contact with the solution L, and the solution L is interposed between the shielding plate 14 and the substrate S. In addition, the shielding plate 14 is parallel to the substrate S (surface of the stage 12) as described above.

In this manner, the solution L is interposed between the shielding plate 14 and the substrate S to have a plate shape. Here, the shape of the solution L in the plane direction of the substrate S becomes the same (substantially the same) as that of the shielding plate 14 due to the surface tension and a capillary phenomenon. In other words, according to the present invention, when the shape and the size of the shielding plate 14 are appropriately set, the organic semiconductor film F with a desired shape and a desired size can be formed. Moreover, when the position in which the substrate S is coated with the solution L and the position of the shielding plate 14 in the x-y direction are appropriately set, the organic semiconductor film F can be formed in a desired position on the substrate S.

It is preferable that the lower surface of the shielding plate 14 is liquid-repellent with respect to the solution L as described above.

The substrate S may be liquid-repellent with respect to the solution L. At this time, it is preferable that the surface energy of the shielding plate 14 is smaller than that of the substrate S as described above.

The film thickness of the solution L in a state in which the solution L is interposed between the shielding plate 14 and the substrate S, that is, the interval between the shielding plate 14 and the substrate S in the z direction is appropriately set according to the concentration or the like of the solution L such that the target film thickness of the organic semiconductor film F can be obtained.

According to the research of the present inventors, the film thickness of the solution L in the state in which the solution L is interposed between the shielding plate 14 and the substrate S is preferably in a range in which the film thickness of the organic semiconductor film F is in a range of 1 nm to 1 rum, more preferably in a range in which the film thickness of the organic semiconductor film F is in a range of 1 nm to 100 nm, and still more preferably in a range in which the film thickness of the organic semiconductor film F is in a range of 1 nm to 50 nm.

From the viewpoint of forming an organic semiconductor element with high mobility, it is preferable that the film thickness of the solution L is set to be in the above-described range.

Here, when the solution L is interposed between the shielding plate 14 and the substrate S, the temperature adjusting means of the stage 12 and/or the shielding plate 14 is driven as needed.

In addition, the timing for driving the temperature adjusting means of the stage 12 and/or the shielding plate 14 is not limited to the time point at which the solution L is interposed between the shielding plate 14 and the substrate S and may be appropriately set according to the type of the organic semiconductor material and/or the solvent contained in the solution L, the concentration of the solution L, and the boiling point of the solvent contained in the solution L so that a desired organic semiconductor material is suitably deposited.

Moreover, the temperature of the stage 12 and the shielding plate 14 can be adjusted in various manners.

That is, only the stage 12 may be heated or cooled, only the shielding plate 14 may be heated or cooled, both of the stage 12 and the shielding plate 14 may be heated, both of the stage 12 and the shielding plate 14 may be cooled, the stage 12 may be heated and then the shielding plate 14 is cooled, or the stage 12 may be cooled and then the shielding plate 14 is heated.

These methods of adjusting the temperature may be appropriately set according to the type of the organic semiconductor material contained in the solution L, the type of the solvent contained in the solution L, the concentration of the solution L, the type of the organic semiconductor element to be manufactured, and the film thickness of the organic semiconductor film F expected to be formed. As the type of the organic semiconductor element to be manufactured, a top-contact type organic semiconductor element and a bottom-contact type organic semiconductor element may be exemplified.

For example, in a case where the solubility of the organic semiconductor material in the solvent contained in the solution L is low, it is possible to prevent extra deposition of the organic semiconductor material in the solution L interposed between the shielding plate 14 and the substrate S and to allow the organic semiconductor material to be deposited only in a desired position, by heating only the stage 12 or both of the stage 12 and the shielding plate 14.

As conceptually illustrated in FIG. 2C, when the solution L is interposed between the shielding plate 14 and the substrate S, the shielding plate 14 is moved to the moving mean 16 side in the y-direction by the moving means 16 in a state of being in parallel with the upper surface of the stage 12. Due to the movement of the shielding plate 14, the solution L is dried (solvent is evaporated) from an exposed portion of the solution L, that is, a portion which is not covered by the shielding plate 14, deposition of the organic semiconductor material begins, and then the organic semiconductor film F is formed.

Moreover, at this time, preferably, the deposition of the organic semiconductor material is promoted by driving the air blowing means 20 and blowing air to the exposed solution L. In other words, the organic semiconductor material is forcibly deposited by blowing air to the exposed solution L. By blowing air, the organic semiconductor material is allowed to be suitably deposited so that the organic semiconductor film F can be formed even when the substrate S is liquid-repellent with respect to the solution L.

Here, the moving velocity of the shielding plate 14 is appropriately set according to the type of the organic semiconductor material contained in the solution L and the type of the solvent, the film thickness of the solution L, the concentration of the solution L, the temperature of the solution L, the area of the organic semiconductor film F to be formed (area of the shielding plate 14), the deposition rate of the organic semiconductor material, the temperature of the stage 12 and/or the shielding plate 14, and the type of the substrate S. In the forming device 10 in the examples of the figures, the moving velocity of the shielding plate 14 indicates the velocity of relative movement between the shielding plate 14 and the stage 12 in the present invention.

According to the research of the present inventors, the moving velocity of the shielding plate 14 is preferably in a range of 1 μm/sec to 1 m/sec, more preferably in a range of 1 μm/sec to 1 mm/sec, and still more preferably in a range of 1 μm/sec to 100 μm/sec.

From the viewpoint of obtaining the organic semiconductor film F with excellent continuity, it is preferable that the moving velocity of the shielding plate 14 is set to be above-described range.

Moreover, as conceptually illustrated in FIG. 2D, the solution L is not covered by the shielding plate 14 at all due to the movement of the shielding plate 14, and the organic semiconductor film F is formed on the substrate S.

As is evident from the description above, according to the present invention, the organic semiconductor film F with a desired shape (for example, an aspect ratio of the vertical and horizontal sides in a case of a rectangular shape) and a desired size can be formed in a desired position on the substrate S having a large area by appropriately setting the position, the shape, and the size of the shielding plate 14. For example, in a case where the organic semiconductor film F is expected to be formed on the entire surface of the substrate S, the substrate S is completely overlapped with the substrate S using the shielding plate having the same shape as that of the substrate S. Alternatively, in a case where the organic semiconductor film F in a rectangular shape is expected to be formed at one corner of the substrate S, the shielding plate 14 in a target rectangular shape may be positioned at the corner at which the organic semiconductor film F of the substrate S is formed.

Moreover, in the present invention, the solution L interposed between the shielding plate 14 and the substrate S is gradually exposed from the end portion by moving the shielding plate 14 and the stage 12 relative to each other in one direction. As a result, the evaporation of the solvent advances from the exposed region of the solution L so that the organic semiconductor material is deposited. For this reason, crystallization of the organic semiconductor material can be promoted in one direction and thus the organic semiconductor film F with excellent crystallinity can be formed even in a large area.

In the present invention, during the formation of the organic semiconductor film F, it is preferable that the vapor pressure in the periphery of the substrate S is increased by the solvent contained in the solvent L and more preferable that the vapor pressure thereof is set to be the saturated vapor pressure.

In the present invention, the deposition direction of the organic semiconductor material can be controlled by the movement of the shielding plate 14. However, since the end portion of the solution L interposed between the shielding plate 14 and the substrate S is open in the X direction, the solvent is evaporated from here and deposition of the organic semiconductor material occurs. As a result, the crystallinity is degraded.

Meanwhile, when the vapor pressure in the periphery of the substrate S is increased and particularly is set to the saturated vapor pressure, the organic semiconductor film F with more excellent crystallinity can be formed by preventing the evaporation of the solvent from the end portion in the x direction.

Examples of the method of increasing the vapor pressure in the periphery of the substrate S include a method covering a substrate using the organic semiconductor film F as the substrate S with a dome-shaped member and filling, the inside thereof with the vapor of the solvent and a method of circulating the vapor of the solvent to both end portions of the substrate S in the x-direction.

In the examples illustrated in FIGS. 1A, 1B, and 2A to 2D, only one shielding plate 14 is used. However, in the present invention, organic semiconductor films F may be formed in plural sites of the substrate S using plural shielding, plates.

For example, as conceptually illustrated in FIG. 3, organic semiconductor films may be formed by being dispersed in four sites on the surface of the substrate S using moving means 32 for holding four shielding plates 30 and moves the shielding plates in the x-y-z direction and the four shielding plates 30. At this time, plural kinds of the shielding plates in different planar shapes may be used or the shielding plates can be replaced by each other as described above. Further, the number of the shielding plates 30 held or moved by the moving means 32 may be set to be changed.

That is, according to the present invention, organic semiconductor films with a desired shape and a desired size can be formed in desired plural sites corresponding to the substrate S having a large area.

Further, in the above-described examples, the shielding plate 14 was dropped after the substrate S is coated with the solution L and the solution L is interposed between the shielding plate 14 and the substrate S.

However, in the present invention, other than the description described above, the space between the shielding plate 14 and the substrate S is filled with the solution L after the shielding plate 14 is arranged by being separated from the substrate S at a predetermined interval, and then the solution L may be interposed between the shielding plate 14 and the substrate S.

According to this method, similarly, organic semiconductor films with excellent crystallinity, a desired shape, and a desired size can be formed on desired plural sites of the substrate S corresponding to the substrate S having a large area.

In the examples illustrated in FIGS. 1A, 1B, 2A to 2D, and 3, the shielding plate 14 is in a rectangular shape. However, in the present invention, various shapes can be applied to the shielding plate.

For example, as conceptually illustrated in FIG. 4A, a shielding plate 38 of which one end portion in the y-direction is in a triangular shape is exemplified. According to such a shielding plate 38, since deposition of the organic semiconductor material is started from the tip of the narrow triangle by moving the shielding plate 38 and the stage 12 relative to each other in a direction opposite to the triangle, an organic semiconductor film with excellent crystallinity can be formed by setting the deposition direction of the organic semiconductor material to one direction.

In addition, for the same reason, as conceptually illustrated in FIG. 4B, the shielding plate 40 having a shape in which one end portion in the y-direction is jagged with plural triangles can be used.

Hereinbefore, the method of forming an organic semiconductor film and the organic semiconductor film forming device of the present invention have been described, but the present invention is not limited to the above-described examples, and various improvements or modifications can be also made without departing from the scope of the present invention.

### EXAMPLES

Hereinafter, the present invention will be described with reference to specific examples of the method of forming an organic semiconductor film and the organic semiconductor film forming device of the present invention.

### Example 1

0.0531 g of organic semiconductor material (TIPS-pentacene (manufactured by Sigma-Aldrich Co. LCC.) was dissolved in 3 mL of toluene to obtain a 2 wt % solution, thereby preparing a solution L.

A silicon plate provided with a thermal oxide film was used as the substrate S for forming an organic semiconductor film. A SAM film of trimethoxy(2-phenethyl)silane in a gas phase was formed on the substrate S.

A glass plate was used as a shielding plate. The shielding plate was immersed in DURASURF HD-1101Z (manufactured by HARVES Co., Ltd.), dried using a blower, and then subjected to a liquid-repellent treatment.

The substrate S was placed on a box-shaped metal stage, and 2 mL of the solution L was added dropwise to the substrate S. Next, the shielding plate was set in the upper portion of the droplets, the lower surface thereof was moved to be closer to the solution L until the lower surface thereof was brought into contact with the solution L in a state of being parallel with the surface of the substrate and held in a position separated from the substrate S, and the space between the substrate and the shielding plate was filled with the solution L.

Next, the stage on which the substrate S was placed was allowed to move in a direction parallel to the shielding plate at a velocity of 20 μm/sec, and formation of an organic film was started from the liquid end side separated from the shielding plate. At the time point at which the shielding plate was completely separated from the substrate S, the substrate was allowed to be stopped.

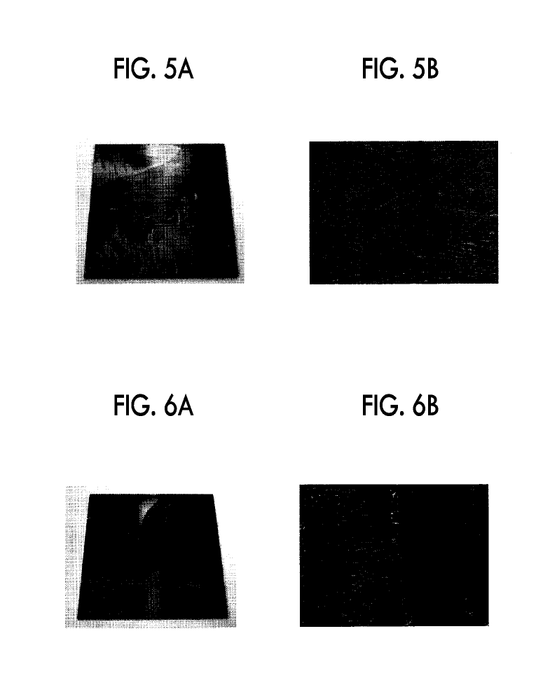

As a result, an organic semiconductor film F illustrated in FIGS. 5A and 5B was formed on the substrate S. In addition, FIG. 5B shows a microphotograph of the organic semiconductor film F shown in FIG. 5A.

### Comparative Example 1

An organic semiconductor film F was formed in the same manner as in Example 1 except that the space between the substrate and the shielding plate was filled with the solution L, the shielding plate was removed therefrom, and then the solution L which was added dropwise to the substrate S was naturally dried.

As a result, the organic semiconductor film F formed on the substrate S was non-uniform as shown in FIGS. 6A and 6B. In addition, FIG. 6B shows a microphotograph of the organic semiconductor film F shown in FIG. 6A.

### Comparative Example 2

An organic semiconductor film F was formed in the same manner as in Example 1 except that a bar having a diameter of 1 cm was brought into contact with the solution L in place of the shielding plate, and then the bar was allowed to move in parallel with the substrate S.

As a result, the organic semiconductor film F formed on the substrate S was non-uniform as in Comparative Example 1.

From the results described above, the effects of the present invention are evident Industrial Applicability

The present invention can be suitably applied to manufacture of organic semiconductor elements using organic semiconductor materials such as TFT. Explanation of References

10: fonning device

12: stage

14, 30, 38, 40: shielding plate

16, 32: moving means

18: coating means

20: air blowing means

What is claimed is:

1. A method of forming an organic semiconductor film which uses a shielding member for covering a solution containing an organic semiconductor material and a solvent when forming the organic semiconductor film on at least a part of a substrate using, the solution, the method comprising:
a process of placing the substrate on a stage;
a process of coating a predetermined position on the surface of the substrate with the solution and positioning the shielding member parallel to the substrate by bringing the shielding member into contact with the solution and separating the shielding member from the substrate or a process of positioning the shielding member in a predetermined position on the substrate parallel to the substrate and separated from the substrate and filling the space between the shielding member and the substrate with the solution by bringing the solution into contact with the shielding member ; and
a process of moving the shielding member and the stage relatively parallel to each other in a predetermined direction, from the state in which the solution is present between the shielding member and the substrate.

2. The method of forming an organic semiconductor film according to claim 1, wherein the surface of the shielding member in contact with the solution is water-repellent with respect to the solution.

3. The method of forming an organic semiconductor film according to claim 1, wherein the surface energy of the shielding member is lower than the surface energy of the substrate.

4. The method of forming an organic semiconductor film according to claim 1, wherein the temperature of at least one of the shielding member or the stage is adjusted.

5. The method of forming an organic semiconductor film according to claim 1, wherein the organic semiconductor material in the solution exposed from the shielding member due to the relative movement between the shielding member and the stage is forcibly deposited.

6. The method of forming an organic semiconductor film according to claim 5, wherein the forced deposition of the organic semiconductor material is carried out by blowing air into the solution.

7. The method for forming an organic semiconductor film according to claim 1, wherein the surface of the substrate is made to be horizontal and placed on the stage.

8. An organic semiconductor film forming device comprising:
a stage on which a substrate is placed;
a shielding member which covers a solution containing an organic semiconductor material and a solvent;
solution supply means for supplying the solution to a predetermined position on the substrate placed on the stage;
position control means for positioning the shielding member in a predetermined position with respect to the surface of the stage on which the substrate is placed, in a state in which the shielding member is separated from the stage and parallel to the surface of the stage on which the substrate is placed; and
relative moving means for moving the shielding member and the stage relatively parallel to each other in a predetermined direction.

9. The organic semiconductor film forming device according to claim 8, further comprising at least one of temperature adjusting means for the stage or temperature adjusting means for the shielding member.

10. The organic semiconductor film forming device according to claim 8, further comprising deposition means for allowing the organic semiconductor material to be forcibly deposited from the solution.

11. The organic semiconductor film forming device according to claim 10, wherein the deposition means is air blowing means.

12. The organic semiconductor film forming device according to claim 8, further comprising angle adjusting means for the surface of the stage.
